(19) United States
(12) Patent Application Publication
(10) Pub. No.: US 2010/0006427 A1
(43) Pub. Date: Jan. 14, 2010

(54) REACTOR FOR CARRYING OUT AN ETCHING METHOD FOR A STACK OF MASKED WAFERS AND AN ETCHING METHOD

(76) Inventors: Joachim Rudhard, Leinfelden-Echterdingen (DE); Christina Leinenbach, Ensdorf (DE)

Correspondence Address: KENYON & KENYON LLP, ONE BROADWAY, NEW YORK, NY, 10004, US

(21) Appl. No.: 11/988,497

(22) PCT Filed: May 29, 2006
(86) PCT No.: PCT/EP2006/062664

§ 371 Date: Sep. 28, 2009

(30) Foreign Application Priority Data
Jul. 6, 2005 (DE) 10 2005 031 602.6

(51) Int. Cl. C23C 14/34; C23F 1/08; C23F 1/00

(52) U.S. Cl. 204/192.32; 156/345.1; 156/345.43; 216/67; 204/298.31

(57) ABSTRACT

A reactor for carrying out an etching method for a stack of masked wafers, using an etching gas, preferably chlorotrifluoride (ClF₃), wherein the reactor includes a device for carrying out a plasma process. An etching method for masked wafers, using an etching gas, preferably chlorotrifluoride (ClF₃), the wafer being pretreated in a plasma process before an etching process, wherein the wafer pretreatment and the etching process for a stack of wafers take place in a reactor chamber.

### FIELD OF THE INVENTION

The present invention relates to a reactor for carrying out an etching method for a stack of masked wafers, as well as an etching method.

### BACKGROUND INFORMATION

Chlorotrifluoride (ClF₃) is known as the process gas for cleaning CVD (chemical vapor deposition) equipment. Furthermore, for some time now, ClF₃ has also found its way into the technology of micropatterning. It stands out by its high selectivity with respect to silicon oxide (SiO₂). This means that silicon (Si) is etched, and as passivation, SiO₂ is used, among others. The etching process runs spontaneously, that is, in a certain process window (pressure, temperature, gas flow) no plasma is required nor any thermal excitation by comparatively high temperatures for the etching process. The individual wafers provided for micropatterning by such an etching process are pretreated in a method step preceding the etching process in a pretreatment chamber and/or a conditioning chamber. They are then removed from the chamber and etched in another chamber, the etching chamber.

### SUMMARY

Example embodiments of the present invention provide a device of the species for the treatment of wafers of the type described at the outset, as well as provide an improved method for treating wafers.

Accordingly, example embodiments of the present invention relate to a reactor for carrying out an etching for a stack of masked wafers which are etched using an etching gas, preferably chlorotrifluoride (ClF₃). The reactor is distinguished in that it also includes a device for carrying out a plasma process.

This procedure is based on the knowledge that, when a plurality of wafers is being processed, as occurs with a stack of wafers, for example, secondary processing events have to be carried out only once. Thus, these process steps required in addition and accompanying the etching process, such as putting the wafer(s) into a process chamber, placing the reactor chamber under vacuum and tempering it are able to be reduced enormously in a time saving and cost saving manner.

This procedure is also based on the knowledge that an improvement in the etching processes may be attained by additionally carrying out plasma processes for cleaning the surface areas of the wafer that are to be etched, possibly even between individual etching steps or possibly even during an etching step. It is preferably regarded as advantageous if a sputtering process, especially an inert-gas sputtering process, is used for this.

Because of the circumstance that the wafer does not have to be removed again from a first pretreatment chamber and/or conditioning chamber, and be placed into a second chamber where the etching process occurs, one may additionally do away with advantageously even the slight, but still existing possibility of a haze on, or damage to the wafer.

The reactor advantageously includes a wafer boat having electrodes, in an additionally advantageous manner the electrodes simultaneously forming mounts for the wafers, so that the latter may be introduced into the reactor cleanly arranged, together with the wafer boat.

For a further increase in capacity of the reactor, the electrodes may even be developed so that they are able to accommodate two wafers.

The electrodes situated in the boat, that are particularly plate-shaped and insulated from one another, are able to be provided with alternating polarity, in an advantageous manner. Therefore, it is possible to carry out a plasma process for treating the wafers held by the electrodes between electrodes respectively arranged adjacently, given an appropriately designed clearance.

A switching unit for changing the polarity of the electrodes additionally broadens the functionality of the reactor.

The wafer boat may be provided with an appropriately developed contact unit, for contacting the electrodes situated in the wafer boat to electrical connections of the reactor or to appropriate supply lines. This contact unit is preferably designed in such a way that a contact connection, which is simple, on the one hand, but also reliable, on the other hand, is ensured from the outside of the reactor to the electrodes.

For the coordination of the individual process steps of the reactor, such as a plasma process, a sputtering process, an etching process, the change between the process steps and the combination of such steps, as well as possibly also preceding and succeeding process steps, the reactor may furthermore include an appropriate control device.

Using a reactor constructed in such a way, etching methods and pretreatment methods or conditioning methods for the wafers to be etched are therefore able to be combined in an overall method sequence, this method sequence taking place in one and the same reactor chamber.

Example embodiments of the present invention are explained in more detail on the basis of the drawings and the subsequent associated description.

### BRIEF DESCRIPTION OF THE DRAWINGS

FIG. 1 a schematic representation of an equipment construction for a reactor for carrying out an etching method for a stack of masked wafers, which is furnished with a plasma generator;

FIG. 2 a schematic sectional representation of a wafer boat region having electrodes and having wafers situated on them, provided for treatment using an etching process and a plasma process;

FIG. 3 a schematic sectional representation of a masked wafer provided for treatment by the reactor according to example embodiments of the present invention;

FIG. 4 a representation corresponding to FIG. 3 having a symbolically shown plasma irradiation;

FIG. 5 the section of the wafer according to FIGS. 3 and 4 after the plasma treatment and

FIG. 6 the portion of the wafer in FIG. 5 during a subsequent ClF₃ process.

### DETAILED DESCRIPTION

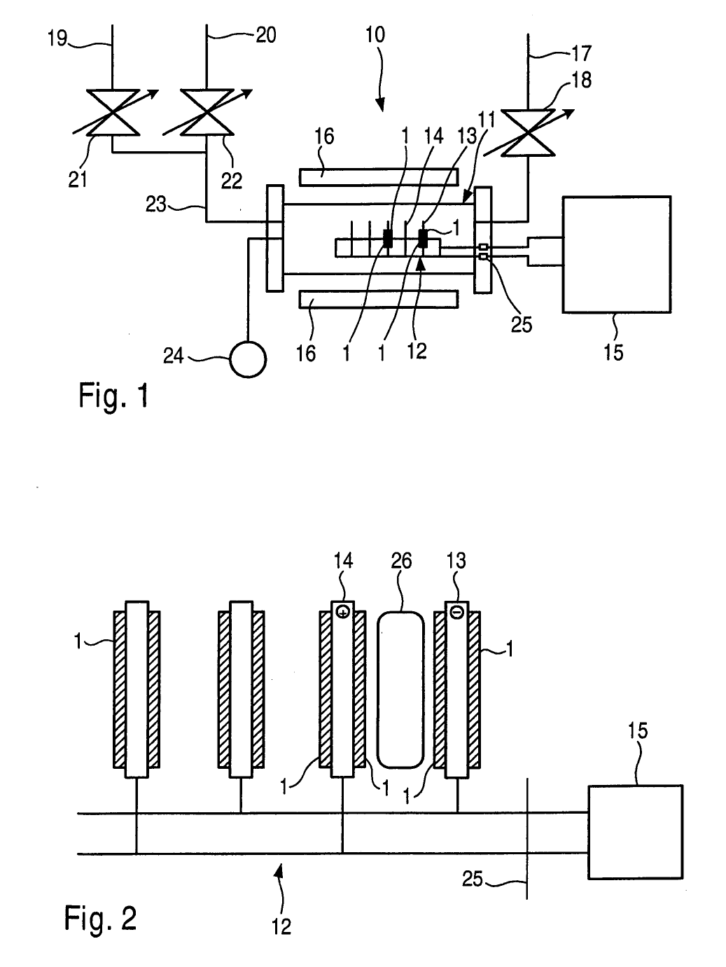

Now, FIG. 1 shows in detail installation 10 having a reactor 11 for carrying out an etching method for a stack of masked wafers. According to example embodiments of the present invention, the reactor is equipped with a plasma generator 15, so that the wafers placed into the reactor for the etching process are able to be pretreated without further intermediate steps and etched at once thereafter. Thus, the reactor makes available both a pretreatment chamber or conditioning chamber and an etching chamber for carrying out a so-called batch etching process, that is, an etching process for a whole stack of wafers, chlorotrifluoride (ClF₃) being preferably used as the etching gas.

Plasma generator 15 is basically used for initiating a plasma process inside the reactor, such a plasma process being able to be carried out before a ClF₃ batch etching process that is to be carried out, subsequently or alternatively or even simultaneously to such an etching process. In particular, in this context, besides the possibility of reducing the reaction temperatures required for a certain method, based on the catalytic effect of the plasma, the possibility is also provided of carrying out a sputtering process, especially an inert-gas sputtering process, for cleaning the surfaces of the wafers that are to be etched.

Wafer boat 12 includes electrodes 13, 14 which are designed so that they are suitable for accommodating wafers 1 that are to be treated in the reactor, preferably even for accommodating two such wafers. Electrodes 13, 14 that are designed to be insulated from each other are situated, in this context, in the wafer boat, having alternating polarity. A switching unit for changing the electrode polarity is able to enhance the functionality of the reactor. Preferably such a switching unit 15 is integrated into plasma generator 15.

For the contacting of electrodes 13, 14 of wafer boat 12 inserted in the reactor, reactor 11 also includes a contact unit 25. Using this, when the wafer boat is installed in the reactor, it is able to be contacted to the electrical terminals of the reactor or to the corresponding supply lines.

In order to be able to control the individual method steps, such as the plasma process, the sputtering process, the etching process and the change between the process steps or their combination, as well as possibly also preceding and succeeding process steps, the reactor may preferably also include a control device 15, which on its part, in turn, is able to be accommodated in plasma generator 15 or to be a part of it.

Besides these essential reactor elements, the equipment furthermore includes the components usually provided for such equipment, a heater 16, a vacuum line 17, a vacuum control valve 18, gas lines 19, 20, valves 21, 22, gas connection 23 as well as a pressure recorder and pressure indicator 24. These elements represent the essential equipment elements, but the listing is not final.

Using equipment including such a reactor, temperatures in the range of 20° C. to 600° C., pressures of a few mTorr to about 8 Torr, and flows of a few sscm ((standard cubic centimeter minute) (standard cm³/minute)) up to a few slm (standard liter/minute) may be set for the treatment of the wafer. Also advantageous is the use of an LPCVD tube (low pressure chemical vapor deposition) for the construction of the reactor, in which the wafer boat is able to be installed.

FIG. 2 shows, again schematically, electrodes 13, 14, as they are situated, for instance, in a wafer boat 12. Wafers 1 are fixed on electrodes 13, 14 which are preferably developed to be plate-shaped, and are able to be sputtered upon activation of plasma generator 15 using plasma region 26, which is also shown symbolically. The polarity of the electrodes is preferably switchable, so that the same treatment conditions are able to be set for each wafer, depending on the switched polarity of electrodes 13, 14.

Electrical contact unit 25 is shown here schematically by a transverse line, which separates region 12 that is allocated to the boat from the region allocated to plasma generator 15.

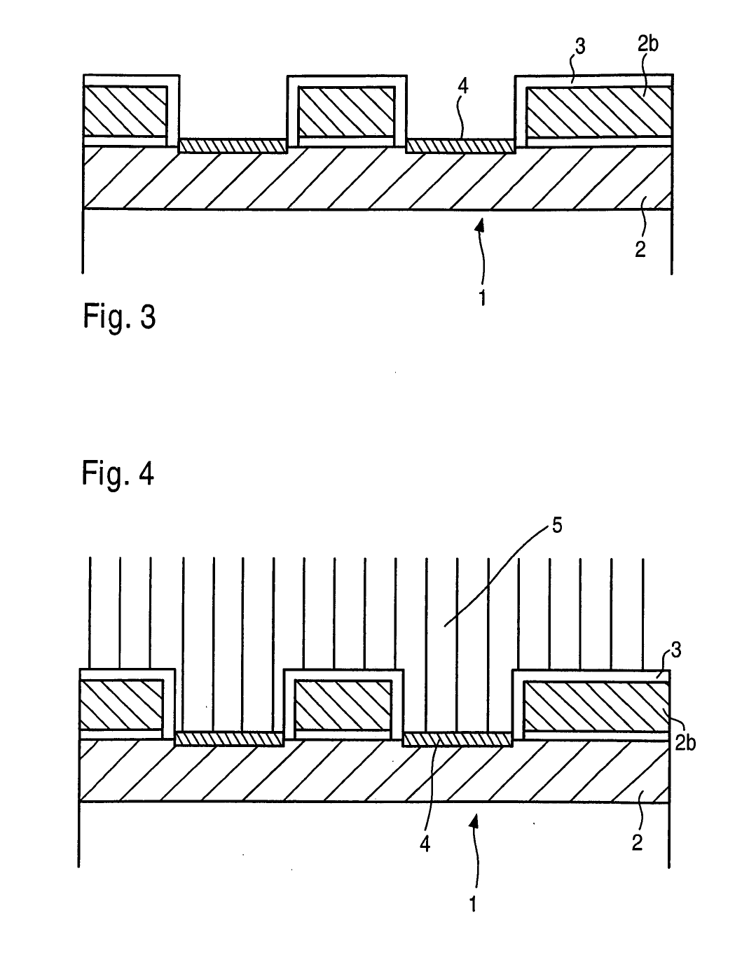

FIGS. 3 to 6 show a partial section of the wafer having a masked surface, during different process steps. FIG. 3 shows a section of a wafer 1 having a layer 2 made of sacrificial material, such as epipoly, LPCVD polysilicon, LPCVD silicon-germanium, or the like. There is a layer 2b over this made of a functional material, such as epipoly, LPCVD polysilicon, LPCVD silicon-germanium or other materials which are coated with a mask 3 made of SiO₂, Si₃N₄, photo-resist or other materials. For the purpose of a functional layer 2b that is protected on all sides from an etching attack from below, a protective layer 2c is located between sacrificial material 2 and functional material 2b.

The protective layer is preferably selected to have a high selectivity with respect to the sacrificial material in the etching process. In this case, it is preferably SiO₂.

Furthermore, between regions having functional material, there is a micromasking 4 made of a natural oxide, oxide residues or general masking residues.

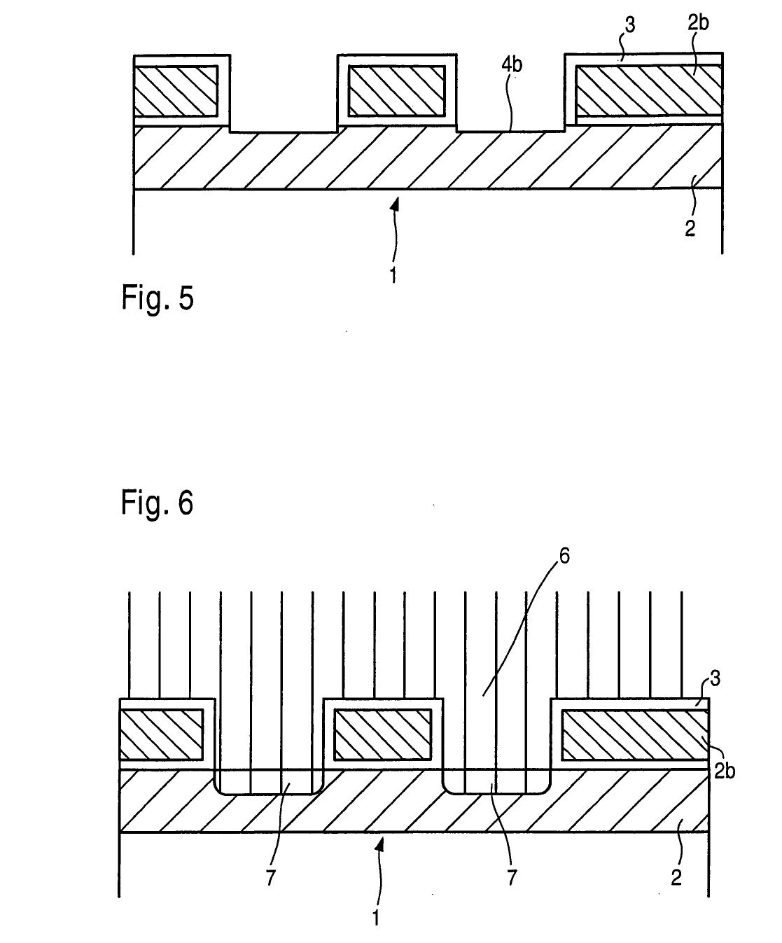

FIG. 4 shows the same construction as FIG. 3, but it differs in showing additionally an activated plasma process by lines 5, that run perpendicularly onto the surface of the wafer, and which corresponds to reference numeral 26 in FIG. 2. Plasma process 5 or even sputtering process 5 is activated after the loading process of the boat while contacting to plasma generator 15, and after a gas and temperature stabilization routine. Thereby wafers 1 that are patterned with oxide mask 3 are able to be freed, by the sputter process, of natural oxide 4 and oxide residues or resist residues from previous processes in the areas to be etched. In the case of a pure sputtering process, for this purpose nitrogen or an inert gas, such as argon, may also be used as process gas. The physical bombardment completely removes natural oxide 4 for the subsequent ClF₃ etching process (FIG. 5). Basically, there might also be possible a physicochemical etching process, given an appropriately suitable selection of process gases and material properties.

Since the etching of the oxide is not selective, the thickness of the mask, for the areas not to be etched, has to be selected to be correspondingly thicker. However, based on the minimum thickness of the natural oxide of a few nm, this is not critical, and may be neglected in most cases.

After natural oxide 4 has been completely removed at the locations to be etched (FIG. 5), the etching process according to FIG. 6 is initiated using ClF₃. The application of ClF₃ on wafer 1 is also shown symbolically in FIG. 6 by lines 6 that are aligned perpendicularly onto the wafer surface.

Sacrificial layer 2 is able to be etched using this etching method in order to set free a functional layer 2b that is protected on all sides. The etching front is able to advance homogeneously because of the unhindered access of the gas to the open areas, and a lateral, inhomogeneous etching attack does not occur.

In case any chemical layer forms on the areas to be etched, because of the ClF₃ etching process and the process control, which chemical layer would hinder the further access of the etching gas to the opened etching surface and would minimize the etch rate, there is also the possibility, as was already noted, of employing an alternating process using sputtering and a ClF₃ etching process, so that there comes about as optimal a treatment result of the wafer as possible.

1-13. (canceled)

14. A reactor for carrying out an etching method for a stack of masked wafers, using an etching gas, comprising:
a device configured to carry out a plasma process.

15. The reactor according to claim 14, wherein the etching gas includes chlorotrifluoride (ClF₃).

16. The reactor according to claim 14, wherein the reactor includes a device configured to carry out an inert-gas sputtering process.

17. The reactor according to claim 14, wherein the reactor includes a wafer boat having electrodes.

18. The reactor according to claim 17, wherein the electrodes include mounts for the wafers.

19. The reactor according to claim 14, wherein an electrode is arranged to accommodate two wafers.

20. The reactor according to claim 17, wherein a switching unit is provided for changing the polarity of the electrodes.

21. The reactor according to claim 17, wherein the wafer boat includes a contact unit for contacting the electrodes to one of (a) electrical connections of the reactor and (b) appropriate supply lines.

22. The reactor according to claim 14, wherein a control device is provided which controls individual method steps including at least one of (a) a plasma process, (b) an etching process, and (c) a change between process steps.

23. The reactor according to claim 23, wherein the method steps include at least one of (a) preceding and (b) succeeding process steps.

24. An etching method for masked wafers, using an etching gas, comprising:
pretreating the wafer in a plasma process before an etching process,
wherein the wafer pretreatment and the etching process for a stack of wafers take place in a reactor chamber.

25. The method according to claim 24, wherein the etching gas includes chlorotrifluoride (ClF₃).

26. The method according to claim 24, wherein the wafer pretreatment and the etching process take place combined in the reactor chamber.

27. The method according to claim 24, wherein the etching method includes an inert-gas sputtering process for the wafer pretreatment.

28. The method according to claim 27, wherein the inert-gas sputtering process takes place at least one of (a) before and (b) during the etching process.

29. The method according to claim 27, wherein the inert-gas sputtering process takes place alternatingly with the etching process.
